(19) United States
(12) Patent Application Publication
(10) Pub. No.: US 2006/0091443 A1
(43) Pub. Date: May 4, 2006

(54) Composite capacitor

(75) Inventors: Kazuhiko Ueda, Fukushima-ken (JP); Hiroyuki Ishiwata, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/269,196

(22) Filed: Oct. 27, 2005

(30) Foreign Application Priority Data
Oct. 29, 2004 (JP) 2004-317365

(51) Int. Cl. H01L 29/94

(52) U.S. Cl. 257/313

(57) ABSTRACT

A composite capacitor includes a laminated substrate in which a plurality of dielectric layers and a plurality of conductive layers are laminated alternately. The laminated substrate includes a first common electrode that is composed of the corresponding conductive layer and is provided in laminated layers of the laminated substrate, a first electrode that is composed of the corresponding conductive layer and is disposed above the first common electrode with one of the dielectric layers between the first electrode and the first common electrode, and a second electrode that is composed of the corresponding conductive layer and is disposed below the first common electrode with one of the dielectric layers between the second electrode and the first common electrode. Each of the first and second electrodes, which oppose the first common electrode, is disposed within an area of the first common electrode.

### BACKGROUND OF THE INVENTION

1. Field of the Invention

The present invention relates to a composite capacitor that is used in various types of electronic circuit units and electrical devices and that is suitably formed in a laminated substrate, in which dielectric layers and conductive layers are laminated.

2. Description of the Related Art

FIG. 13 is a circuit diagram of a typical high-frequency filter circuit that is used in various types of electronic circuit units and electrical devices. In the high-frequency filter circuit shown in FIG. 13, a composite capacitor is used. In the composite capacitor, a capacitor C1 is connected in series to a capacitor C2 and the capacitor C2 is connected in series to a capacitor C3.

FIG. 11 is an exploded perspective view of a known composite capacitor. FIG. 12 is a cross-sectional view of a main part of the known composite capacitor.

Next, the structure of the known composite capacitor shown in FIG. 13 will be described with reference to FIGS. 11 and 12. A laminated substrate 51 includes a plurality of dielectric layers 61 to 65 and a plurality of conductive layers (described below) laminated therein.

The dielectric layer 61 at a lower layer includes a ground electrode 52 that has a large area. The dielectric layer 62 disposed on the dielectric layer 61 includes a first electrode 53 and a second electrode 54, each electrode being composed of a conductive layer. The first electrode 53 and the second electrode 54 are disposed side by side, oppose the ground electrode 52 composed of a conductive layer, and include lead-out parts 53a and 54a, respectively.

The capacitor C1 is formed between the ground electrode 52 and the first electrode 53, and the capacitor C2 is formed between the ground electrode 52 and the second electrode 54. Since the ground electrode 52 is a common electrode of the capacitors C1 and C2, the capacitor C1 is connected in series to the capacitor C2.

The dielectric layer 63 disposed on a layer in which the second electrode 54 is formed includes a third electrode 55 composed of a conductive layer and a coil L. The third electrode 55 is connected to the first electrode 53 and opposes the second electrode 54. A capacitor C32 is formed between the second electrode 54 and the third electrode 55.

The dielectric layer 64 disposed on a layer in which the third electrode 55 is formed includes a fourth electrode 56 composed of a conductive layer and the coil L. The fourth electrode 56 is connected to the second electrode 54 and opposes the third electrode 55. A capacitor C31 is formed between the third electrode 55 and the fourth electrode 56. Since the capacitor C31 is formed between the third electrode 55, which is a common electrode of the capacitors C31 and C32, and the fourth electrode 56, the capacitor C32 is formed between the second electrode 54 and the third electrode 55, and the second electrode 54 and the fourth electrode 56 are connected to each other, the capacitors C31 and C32 are connected in parallel and form the capacitor C3. Since the second electrode 54 is a common electrode of the capacitors C2 and C32, the capacitor C2 is connected in series to the capacitor C32. In this way, the known composite capacitor is formed (see Japanese Unexamined Patent Application Publication No. 5-335866, for example).

In the known composite capacitor, the first electrode 53 and the second electrode 54 are disposed side by side in the horizontal direction, these electrodes opposing the ground electrode 52, which is the common electrode. Thus, the size of the known composite capacitor in the horizontal direction is large.

Moreover, the capacitors C31 and C32, which are respectively formed by the fourth electrode 56 and the second electrode 54 opposing the third electrode 55, are connected in parallel to form the capacitor C3 because the second electrode 54 and the fourth electrode 56 are connected to each other. The capacitors C2 and C32 connected in series are respectively formed by the ground electrode 52 and the third electrode 55 opposing the second electrode 54. Thus, the areas of individual electrodes opposing other electrodes may vary due to shifts in the horizontal alignment of the laminated dielectric layers 61 to 65 that occur in the manufacturing process of the laminated substrate 51, and an accurate capacitance value cannot be obtained.

Moreover, in the case of the capacitors C2 and C32 connected in series, the ground electrode 52 may oppose the third electrode 55 due to the shifts in alignment of the laminated layers, and stray capacitance between the ground electrode 52 and the third electrode 55 may increase. This stray capacitance impairs circuit characteristics.

In the known composite capacitor, the first electrode 53 and the second electrode 54 are disposed side by side in the horizontal direction, these electrodes opposing the ground electrode 52. Thus, the size of the known composite capacitor in the horizontal direction is disadvantageously large.

Moreover, when the third electrode 55 and the ground electrode 52 having the second electrode 54 as a common electrode are disposed at a layer on top of and a layer under the second electrode 54, respectively, or the fourth electrode 56 and the second electrode 54 having the third electrode 55 as a common electrode are disposed at a layer on top of and a layer under the third electrode 55, respectively, an accurate capacitance value cannot be obtained due to the shifts in alignment of the laminated layers. Moreover, when the third electrode 55 and the ground electrode 52 having the second electrode 54 as a common electrode are disposed at a layer on top of and a layer under the second electrode 54, respectively, an undesirable stray capacitance increases, and this stray capacitance disadvantageously impairs circuit characteristics.

### SUMMARY OF THE INVENTION

Accordingly, it is an object of the present invention to provide a composite capacitor of a small size in which an accurate capacitance value is obtained and an increase in stray capacitance is suppressed.

As a first solution for solving the problems described above, a composite capacitor includes a laminated substrate in which a plurality of dielectric layers and a plurality of conductive layers are laminated alternately. The laminated substrate includes a first common electrode that is composed of the corresponding conductive layer and is provided in laminated layers of the laminated substrate, a first electrode that is composed of the corresponding conductive layer and is disposed above the first common electrode with one of the dielectric layers between the first electrode and the first common electrode, and a second electrode that is composed of the corresponding conductive layer and is disposed below the first common electrode with one of the dielectric layers between the second electrode and the first common electrode. Each of the first and second electrodes, which oppose the first common electrode, is disposed within an area of the first common electrode.

As a second solution, in the composite capacitor, the laminated substrate may further include at least one of a second common electrode that is composed of the corresponding conductive layer, is connected to the first common electrode, and is disposed above and opposes the first electrode with one of the dielectric layers between the first electrode and the second common electrode, the first electrode, which opposes the second common electrode, being disposed within an area of the second common electrode; and a third common electrode that is composed of the corresponding conductive layer, is connected to the first common electrode, and is disposed below and opposes the second electrode with one of the dielectric layers between the second electrode and the third common electrode, the second electrode, which opposes the third common electrode, being disposed within an area of the third common electrode.

As a third solution, in the composite capacitor, the first common electrode and the at least one of the second and third common electrodes may be connected to each other through a connecting conductor composed of a through hole or a side electrode.

A composite capacitor according to the present invention includes a laminated substrate in which a plurality of dielectric layers and a plurality of conductive layers are laminated alternately. The laminated substrate includes a first common electrode that is composed of the corresponding conductive layer and is provided in laminated layers of the laminated substrate, a first electrode that is composed of the corresponding conductive layer and is disposed above the first common electrode with one of the dielectric layers between the first electrode and the first common electrode, and a second electrode that is composed of the corresponding conductive layer and is disposed below the first common electrode with one of the dielectric layers between the second electrode and the first common electrode. Each of the first and second electrodes, which oppose the first common electrode, is disposed within an area of the first common electrode.

That is to say, the first and second electrodes and the first common electrode are laminated in the vertical direction. Thus, the size of the composite capacitor in the horizontal direction can be decreased as compared with a known composite capacitor. Moreover, each of the first and second electrodes, which oppose the first common electrode, is disposed within the area of the first common electrode. Thus, even when shifts in alignment of the laminated layers of the first and second electrodes and the first common electrode occur in the generating process of the laminated layers of the laminated substrate, the first and second electrodes do not overlap the first common electrode, and an accurate capacitance value can be obtained. Moreover, stray capacitance can be decreased, and circuit characteristics can be improved.

Furthermore, the laminated substrate may further include at least one of a second common electrode that is composed of the corresponding conductive layer, is connected to the first common electrode, and is disposed above and opposes the first electrode with one of the dielectric layers between the first electrode and the second common electrode, the first electrode, which opposes the second common electrode, being disposed within an area of the second common electrode; and a third common electrode that is composed of the corresponding conductive layer, is connected to the first common electrode, and is disposed below and opposes the second electrode with one of the dielectric layers between the second electrode and the third common electrode, the second electrode, which opposes the third common electrode, being disposed within an area of the third common electrode. Thus, the composite capacitor is small in the horizontal direction and has a large capacitance value, and an accurate capacitance value can be obtained.

Furthermore, the first common electrode and the at least one of the second and third common electrodes may be connected to each other through a connecting conductor composed of a through hole or a side electrode. Thus, the composite capacitor has a simple structure and can be efficiently manufactured.

### BRIEF DESCRIPTION OF THE DRAWINGS

FIG. 1 is a cross-sectional view of a main part of a composite capacitor according to a first embodiment of the present invention;

FIG. 2 is an exploded perspective view of the composite capacitor according to the first embodiment of the present invention;

FIG. 3 is a circuit diagram of the composite capacitor according to the first embodiment of the present invention;

FIG. 4 is a perspective view of a composite capacitor according to a second embodiment of the present invention;

FIG. 5 is a cross-sectional view of a main part of the composite capacitor according to the second embodiment of the present invention;

FIG. 6 is an exploded perspective view of the composite capacitor according to the second embodiment of the present invention;

FIG. 7 is a circuit diagram of the composite capacitor according to the second embodiment of the present invention;

FIG. 8 is a perspective view of a composite capacitor according to a third embodiment of the present invention;

FIG. 9 is a circuit diagram of the composite capacitor according to the third embodiment of the present invention;

FIG. 10 is a circuit diagram of a composite capacitor according to a fourth embodiment of the present invention;

FIG. 11 is an exploded perspective view of a known composite capacitor;

FIG. 12 is a cross-sectional view of a main part of the known composite capacitor; and

FIG. 13 is a circuit diagram of a high-frequency filter circuit to which the known composite capacitor is applied.

### DESCRIPTION OF THE PREFERRED EMBODIMENTS

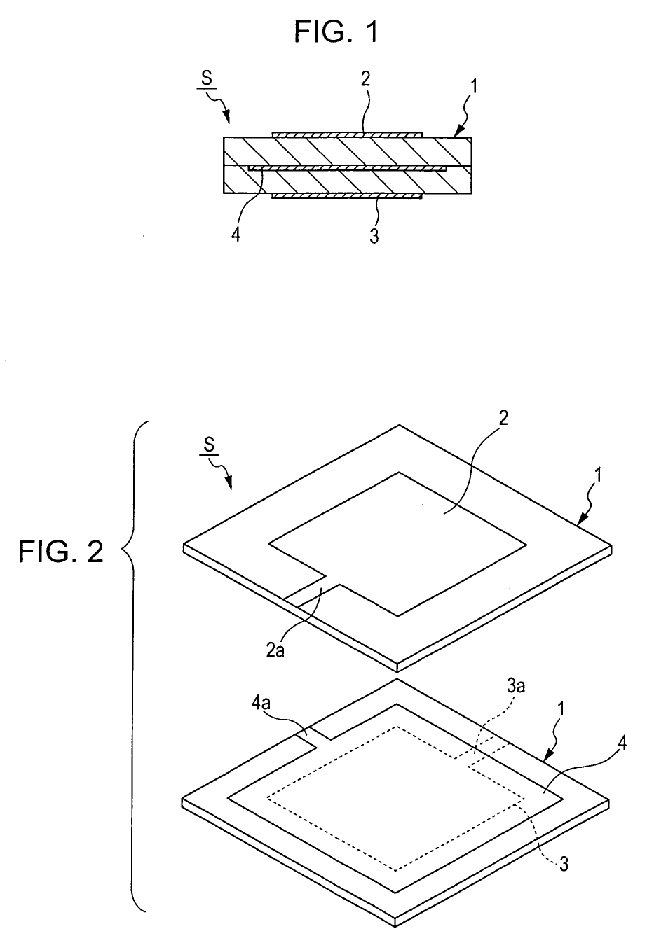

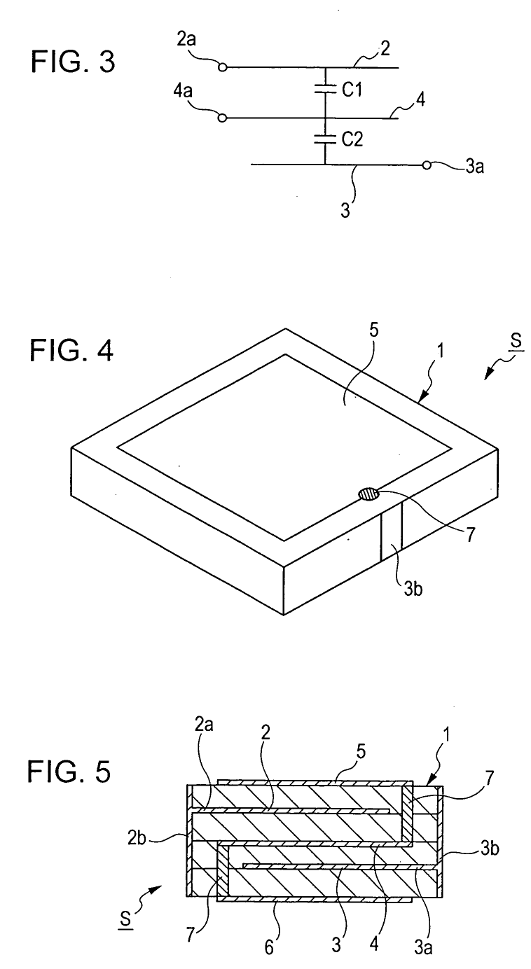

The drawings of composite capacitors according to the present invention will be described. FIG. 1 is a cross-sectional view of a main part of a composite capacitor according to a first embodiment of the present invention. FIG. 2 is an exploded perspective view of the composite capacitor according to the first embodiment of the present invention. FIG. 3 is a circuit diagram of the composite capacitor according to the first embodiment of the present invention.

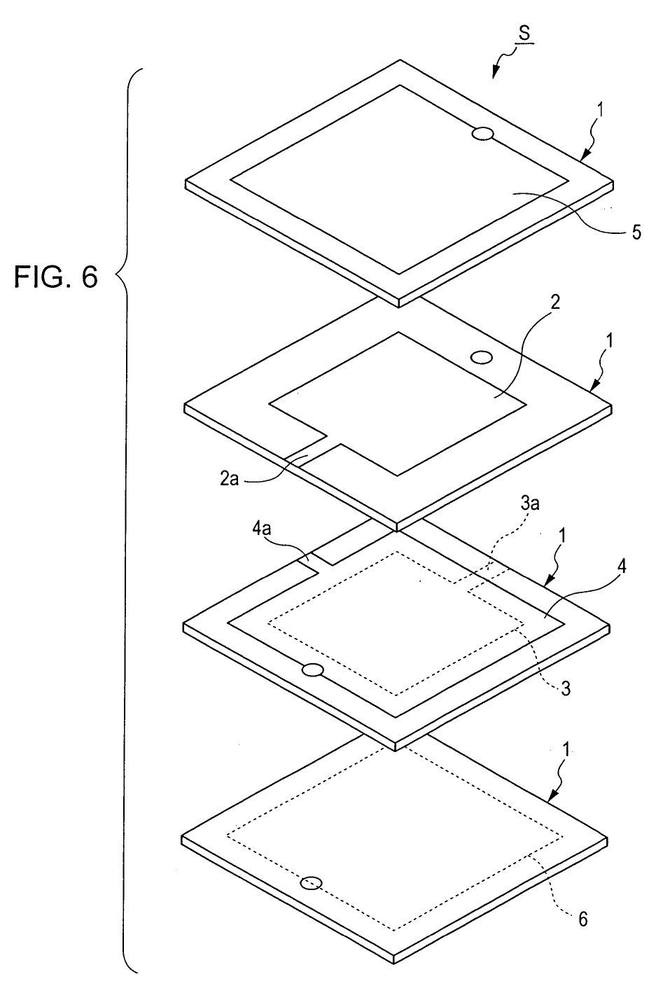

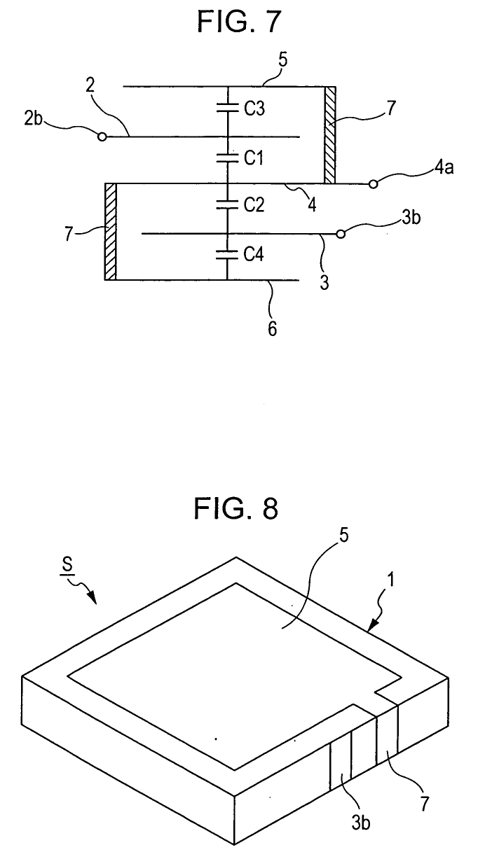

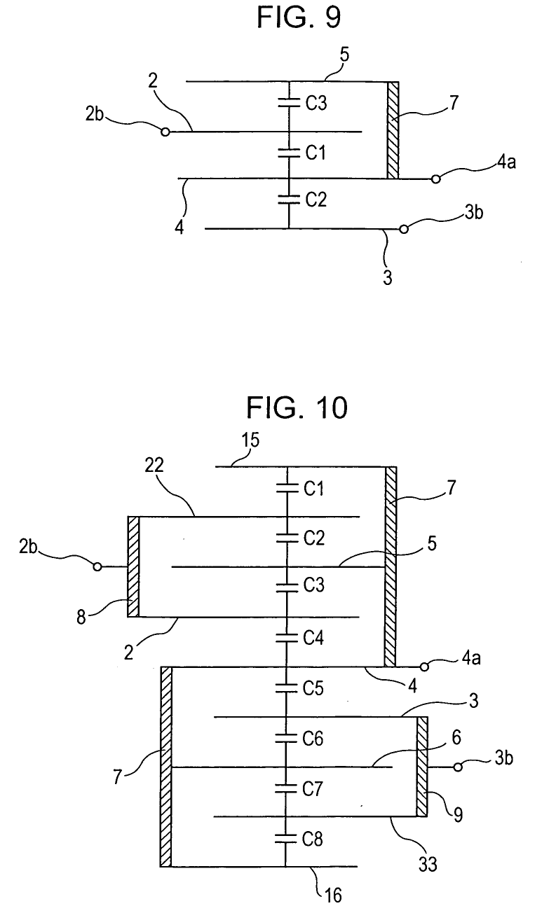

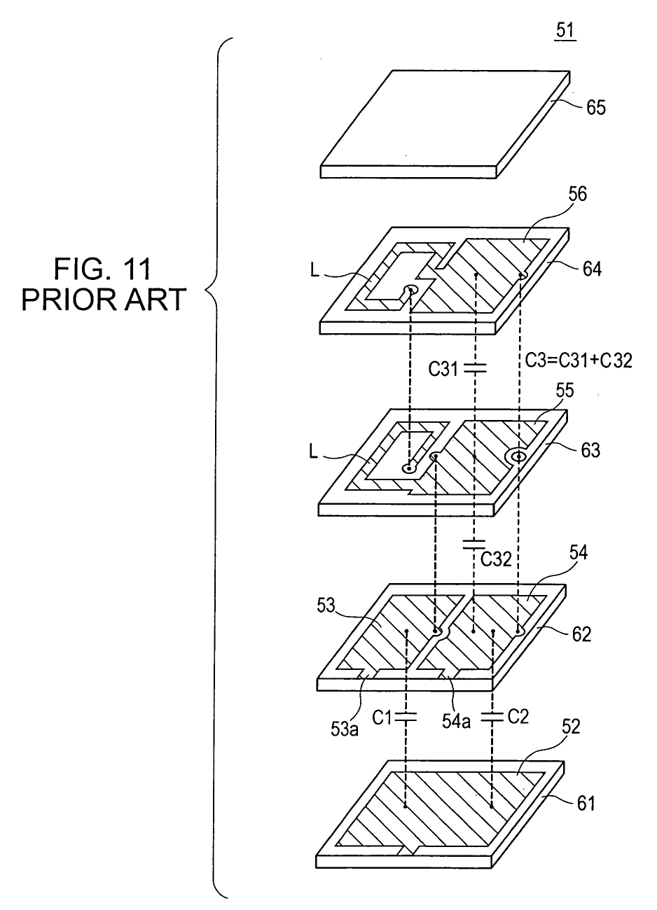

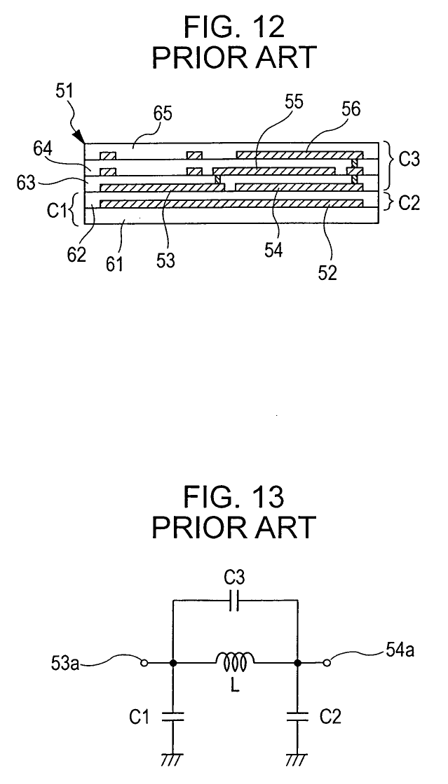

FIG. 4 is a perspective view of a composite capacitor according to a second embodiment of the present invention. FIG. 5 is a cross-sectional view of a main part of the composite capacitor according to the second embodiment of the present invention. FIG. 6 is an exploded perspective view of the composite capacitor according to the second embodiment of the present invention. FIG. 7 is a circuit diagram of the composite capacitor according to the second embodiment of the present invention. FIG. 8 is a perspective view of a composite capacitor according to a third embodiment of the present invention. FIG. 9 is a circuit diagram of the composite capacitor according to the third embodiment of the present invention. FIG. 10 is a circuit diagram of a composite capacitor according to a fourth embodiment of the present invention.

Next, the structure of the composite capacitor according to the first embodiment of the present invention will be described with reference to FIGS. 1 and 3. A laminated substrate S includes a plurality of dielectric layers 1 and a plurality of conductive layers (described below) laminated therein. A first electrode 2 is disposed on the upper surface of the upper layer of the dielectric layers 1. The first electrode 2 is composed of a conductive layer and includes a lead-out part 2a. A second electrode 3 is disposed on the lower surface of the lower layer of the dielectric layers 1. The second electrode 3 is composed of a conductive layer and includes a lead-out part 3a. Moreover, a first common electrode 4 composed of a conductive layer is provided in the laminated layers of the dielectric layers 1. The first common electrode 4 opposes the first electrode 2 and the second electrode 3 with the individual dielectric layers 1 therebetween and includes a lead-out part 4a.

The first common electrode 4 is formed so as to be larger than each of the first and second electrodes. Each of the first electrode 2 and the second electrode 3 is disposed within the area of the first common electrode 4 and opposes the first common electrode 4. A capacitor C1 is formed between the first electrode 2 and the first common electrode 4, and a capacitor C2 is formed between the second electrode 3 and the first common electrode 4. Thus, as shown in FIG. 3, the capacitors C1 and C2 are disposed between the lead-out parts 2a and 3a. A desired electrical circuit is connected to the lead-out parts 2a, 3a, and 4a. In this way, the composite capacitor according to the present invention is formed.

FIGS. 4 to 7 show the composite capacitor according to the second embodiment of the present invention. The structure of the second embodiment will be described. A laminated substrate S includes a second common electrode 5 and a third common electrode 6. The second common electrode 5 is composed of a conductive layer and is disposed on one of the dielectric layers 1, the dielectric layer being disposed on top of a first electrode 2. The third common electrode 6 is composed of a conductive layer and is disposed on one of the dielectric layers 1, the dielectric layer being disposed under a second electrode 3. The second common electrode 5 and the third common electrode 6 are connected to a first common electrode 4 through a connecting conductor 7 composed of a through hole.

The second common electrode 5 and the third common electrode 6 are formed so as to be larger than the first electrode 2 and the second electrode 3, respectively. The first electrode 2 is disposed within the area of the second common electrode 5 and opposes the second common electrode 5. The second electrode 3 is disposed within the area of the third common electrode 6 and opposes the third common electrode 6.

Even though the second common electrode 5 opposes the first common electrode 4 at a portion that overlaps the first electrode 2 and the third common electrode 6 opposes the first common electrode 4 at a portion that overlaps the second electrode 3, the first common electrode 4, the second common electrode 5, and the third common electrode 6 have the same electrical potential. Thus, stray capacitance is not generated.

Since the first electrode 2 and the second electrode 3 are formed in the laminated layers of the laminated substrate S, lead-out parts 2a and 3a extend from the first electrode 2 and the second electrode 3, respectively, to side faces of the laminated substrate S, and terminals 2b and 3b, each terminal being composed of a side electrode on a side face, are formed. In the second embodiment having such a structure, as shown in FIG. 7, a capacitor C3 formed between the first electrode 2 and the second common electrode 5 and a capacitor C4 formed between the second electrode 3 and the third common electrode 6 are added to the composite capacitor according to the first embodiment. Thus, the capacitors C1 to C4 are disposed between the terminals 2b and 3b.

FIGS. 8 and 9 show the composite capacitor according to the third embodiment of the present invention. In the third embodiment, the third common electrode 6 in the second embodiment is removed, and the first common electrode 4 and the second common electrode 5 in the second embodiment are connected to each other through a connecting conductor 7 composed of a side electrode on a side face of the laminated substrate S.

Other structure is the same as that in the second embodiment. The same numbers are assigned to the same components, and the description of these components is omitted here.

In the composite capacitor according to the third embodiment having such a structure, as shown in FIG. 9, capacitors C1 to C3 are disposed between terminals 2b and 3b.

Although the second common electrode 5 is provided in the third embodiment described above, it is apparent that the third common electrode 6 may be provided instead of the second common electrode 5.

FIG. 10 shows the composite capacitor according to the fourth embodiment of the present invention. The fourth embodiment will now be described. A third electrode 22 and a fourth electrode 33 are added to the second embodiment. The third electrode 22 composed of a conductive layer is connected to the first electrode 2 through a connecting conductor 8, and is disposed on one of the dielectric layers 1, the dielectric layer being disposed on top of the second common electrode 5. The fourth electrode 33 composed of a conductive layer is connected to the second electrode 3 through a connecting conductor 9, and is disposed on one of the dielectric layers 1, the dielectric layer being disposed under the third common electrode 6.

Moreover, in the fourth embodiment, a fourth common electrode 15 and a fifth common electrode 16 are provided. The fourth common electrode 15 composed of a conductive layer is connected to the second common electrode 5 through the connecting conductor 7, and is disposed on one of the dielectric layers 1, the dielectric layer being disposed on top of the third electrode 22. The fifth common electrode 16 composed of a conductive layer is connected to the third common electrode 6 through the connecting conductor 7, and is disposed on one of the dielectric layers 1, the dielectric layer being disposed under the fourth electrode 33.

The third electrode 22 is disposed within the area of each of the second common electrode 5 and the fourth common electrode 15 and opposes the second common electrode 5 and the fourth common electrode 15. The fourth electrode 33 is disposed within the area of each of the third common electrode 6 and the fifth common electrode 16 and opposes the third common electrode 6 and the fifth common electrode 16.

Other structure is the same as that in the second embodiment. The same numbers are assigned to the same components, and the description of these components is omitted here.

In the composite capacitor according to the fourth embodiment having such a structure, as shown in FIG. 10, the capacitors C1 to C4 are formed among the first electrode 2, the third electrode 22, the first common electrode 4, the second common electrode 5, and the fourth common electrode 15, and the capacitors C5 to C8 are formed among the second electrode 3, the fourth electrode 33, the first common electrode 4, the third common electrode 6, and the fifth common electrode 16. Consequently, the capacitors C1 to C8 are disposed between the terminals 2b and 3b.

What is claimed is:

1. A composite capacitor comprising:
a laminated substrate in which a plurality of dielectric layers and a plurality of conductive layers are laminated alternately, the laminated substrate comprising:
a first common electrode that is composed of the corresponding conductive layer and is provided in laminated layers of the laminated substrate;
a first electrode that is composed of the corresponding conductive layer and is disposed above the first common electrode with one of the dielectric layers between the first electrode and the first common electrode; and
a second electrode that is composed of the corresponding conductive layer and is disposed below the first common electrode with one of the dielectric layers between the second electrode and the first common electrode,
each of the first and second electrodes, which oppose the first common electrode, being disposed within an area of the first common electrode.

2. The composite capacitor according to claim 1, wherein the laminated substrate further comprises at least one of:
a second common electrode that is composed of the corresponding conductive layer, is connected to the first common electrode, and is disposed above and opposes the first electrode with one of the dielectric layers between the first electrode and the second common electrode, the first electrode, which opposes the second common electrode, being disposed within an area of the second common electrode; and
a third common electrode that is composed of the corresponding conductive layer, is connected to the first common electrode, and is disposed below and opposes the second electrode with one of the dielectric layers between the second electrode and the third common electrode, the second electrode, which opposes the third common electrode, being disposed within an area of the third common electrode.

3. The composite capacitor according to claim 2, wherein the first common electrode and the at least one of the second and third common electrodes are connected to each other through a connecting conductor composed of a through hole or a side electrode.
